(19) United States
(12) Patent Application Publication
(10) Pub. No.: US 2024/0258254 A1
(43) Pub. Date: Aug. 1, 2024

(54) BONDING PAD, INTEGRATED CIRCUIT ELEMENT, AND INTEGRATED CIRCUIT DEVICE

(71) Applicant: Mitsubishi Electric Corporation, Tokyo (JP)

(72) Inventors: Yuki TERADO, Tokyo (JP); Kazuya HOKAZONO, Tokyo (JP); Hongbo ZHANG, Tokyo (JP); Shiori UOTA, Tokyo (JP)

(73) Assignee: Mitsubishi Electric Corporation, Tokyo (JP)

(21) Appl. No.: 18/534,294

(22) Filed: Dec. 8, 2023

(30) Foreign Application Priority Data
Jan. 27, 2023 (JP) 2023-011194

(51) Int. Cl. H01L 23/00; H01L 23/495; H01L 25/16

(52) U.S. Cl. CPC H01L 24/05; H01L 23/49537; H01L 24/48; H01L 25/16; H01L 2224/05084; H01L 2224/05089; H01L 2224/05573; H01L 2224/48137; H01L 2224/48245

(57) ABSTRACT

The bonding pad includes a surface electrode layer that has a first surface; a resistance layer that has a second surface; a stress buffer layer that is disposed between the surface electrode layer and the resistance layer in the first direction; and a connecting member that connects the surface electrode layer and the stress buffer layer in the first direction. The connecting member includes an insulator that is in contact with the each of the surface electrode layer and the stress buffer layer in the first direction, and a plurality of plugs that are in contact with the insulator in the direction orthogonal to the first direction and electrically connect the surface electrode layer and the stress buffer layer. In the first direction, a thickness of the stress buffer layer is larger than a thickness of the surface electrode layer.

### CROSS REFERENCE TO RELATED APPLICATIONS

This nonprovisional application is based on Japanese Patent Application No. 2023-011194 filed on Jan. 27, 2023, with the Japan Patent Office, the entire contents of which are hereby incorporated by reference.

### BACKGROUND OF THE INVENTION

### Field of the Invention

The present disclosure relates to a bonding pad, an integrated circuit element, and an integrated circuit device.

### Description of the Background Art

In recent years, in an integrated circuit element included in an integrated circuit, in order to achieve circuit integration and miniaturization, a multilayer structure in which a plurality of wiring layers and insulating layers for electrically insulating the plurality of the wiring layers are laminated has been adopted. Accordingly, the multilayer structure similar to the integrated circuit has been adopted also in a bonding pad of the integrated circuit element in order to simplify a manufacturing process and reduce man-hours.

Japanese Patent Laying-Open No. 2000-195866 discloses a bonding pad including an upper wiring, an intermediate wiring, a lower wiring, an integrated mesh-type tungsten plug electrically connecting the wirings, and a plurality of island-type insulators existing in the integrated mesh-type tungsten plug and surrounded by the integrated mesh-type tungsten plug.

### SUMMARY OF THE INVENTION

Generally, the bonding pad is subjected to ultrasonic bonding to a conductive member such as a wire. In the bonding pad described in Japanese Patent Laying-Open No. 2000-195866, when the conductive member is subjected to the ultrasonic bonding to the upper wiring, a load due to weighting in a lamination direction of the upper wiring, the intermediate wiring, and the lower wiring is applied to the bonding pad. Moreover, a load due to ultrasonic vibration is applied to the bonding pad in a direction orthogonal to the lamination direction during the ultrasonic bonding.

In the bonding pad described in Japanese Patent Laying-Open No. 2000-195866, since a Young's modulus of tungsten constituting the integrated mesh-type tungsten plug is higher than a Young's modulus of an insulator material constituting the island-type insulator, a structure including the integrated mesh-type tungsten plug and the island-type insulator hardly buffers a stress. Therefore, the stress may concentrate on the integrated mesh-type tungsten plug and cracks may occur during the ultrasonic bonding with the load applied as described above. In a case where the cracks occur in the integrated mesh-type tungsten plug, bondability between the conductive member and the bonding pad may be deteriorated, and the conductive member may be peeled off from the bonding pad similarly to a case where the cracks occur in the island-type insulator formed in the plug.

A main object of the present disclosure is to provide a bonding pad in which cracks hardly occur in each of a plug and an insulator and bondability between a conductive member and the bonding pad is hardly deteriorated as compared with a conventional bonding pad, an integrated circuit element including the bonding pad, and an integrated circuit device including the integrated circuit element.

The bonding pad according to the present disclosure is a bonding pad of the integrated circuit element included in the integrated circuit device. The bonding pad includes a surface electrode layer having a first surface; a resistance layer having a second surface disposed at an interval from the first surface in a first direction orthogonal to the first surface and facing a side opposite to the first surface; a stress buffer layer disposed between the surface electrode layer and the resistance layer in the first direction; and a connecting member connecting the surface electrode layer and the stress buffer layer in the first direction and being in contact with each of the surface electrode layer and the stress buffer layer. The stress buffer layer extends over the entire bonding pad in a direction orthogonal to the first direction. The connecting member includes an insulator that is in contact with the each of the surface electrode layer and the stress buffer layer in the first direction; and at least one plug that is in contact with the insulator in the direction orthogonal to the first direction and electrically connects the surface electrode layer and the stress buffer layer. A thickness of the stress buffer layer in the first direction is larger than a thickness of the surface electrode layer in the first direction.

The above and other objects, features, aspects and advantages of the present invention will become apparent from detailed description of the present invention below to be understood referring to accompanying drawings.

### BRIEF DESCRIPTION OF THE DRAWINGS

FIG. 1 is a cross-sectional view for illustrating an integrated circuit element and an integrated circuit device according to a first embodiment.

FIG. 2 is a partially enlarged perspective view of a region II in FIG. 1.

FIG. 3 is a cross-sectional view for illustrating a bonding pad according to the first embodiment.

FIG. 4 is a cross-sectional view as viewed from an arrow IV-IV in FIG. 3.

FIG. 5 is a cross-sectional view for illustrating a bonding pad according to a second embodiment.

FIG. 6 is a cross-sectional view for illustrating a bonding pad according to a third embodiment.

FIG. 7 is a cross-sectional view for illustrating a bonding pad according to a fourth embodiment.

FIG. 8 is a cross-sectional view as viewed from an arrow VIII-VIII in FIG. 7.

FIG. 9 is a cross-sectional view for illustrating a variation of the bonding pad according to the first embodiment.

### DESCRIPTION OF THE PREFERRED EMBODIMENTS

Hereinafter, embodiments of the present disclosure will be described with reference to the drawings. Note that, hereinafter, the same or equivalent units are denoted by the same reference numerals, and redundant description will not be repeated.

### <Configuration of Integrated Circuit Device and Integrated Circuit Element>

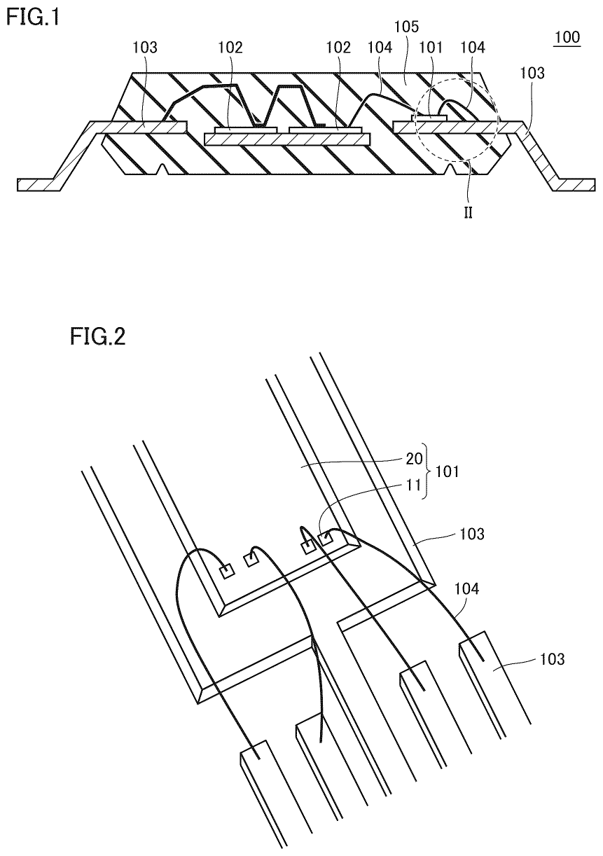

As illustrated in FIG. 1, an integrated circuit device 100 according to an embodiment of the present disclosure is, for example, a power module. Integrated circuit device 100 includes an integrated circuit element 101, a power semiconductor element 102, a plurality of lead frames 103, a plurality of wires 104 (conductive members), and a sealing member 105. Integrated circuit element 101 is, for example, a control semiconductor element that controls actions of power semiconductor element 102.

As illustrated in FIGS. 1 and 2, integrated circuit element 101 is mounted on, for example, one lead frame 103, and electrically connected to another lead frame 103 via wires 104. Integrated circuit element 101 includes a plurality of bonding pads 11. Each of the plurality of bonding pads 11 is subjected to the ultrasonic bonding to one end of a corresponding one of the plurality of wires 104. Another end of each of the plurality of wires 104 is subjected to the ultrasonic bonding to a respective one of lead frames 103.

The each of bonding pads 11 of integrated circuit element 101 is one of bonding pads according to the first embodiment to the fourth embodiment to be described later.

Integrated circuit element 101 further includes a multilayer structure 20. Multilayer structure 20 includes a first wiring layer and a second wiring layer that are laminated at an interval therebetween and electrically connected to bonding pads 11; an insulating layer that is sandwiched between the first wiring layer and the second wiring layer and electrically insulates the first wiring layer and the second wiring layer; and a plug that is embedded in the insulating layer and electrically connects the first wiring layer and the second wiring layer.

### First Embodiment

### <Configuration of Bonding Pad>

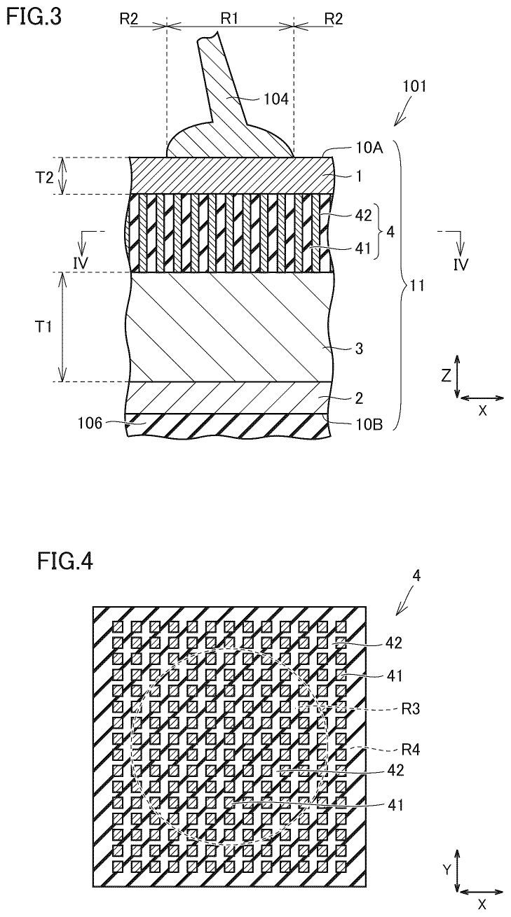

Bonding pad 11 according to the first embodiment will be described with reference to FIGS. 3 and 4. Note that, in FIG. 3, illustration of a configuration other than bonding pad 11 is omitted.

As illustrated in FIG. 3, bonding pad 11 has a first surface 10A, and a second surface 10B that is disposed at an interval from first surface 10A in a first direction Z orthogonal to first surface 10A and faces a side opposite to first surface 10A. Note that, in the present description, a direction from second surface 10B toward first surface 10A in first direction Z may be referred to as an up direction. First surface 10A and second surface 10B are two end surfaces of bonding pad 11 in first direction Z. In integrated circuit element 101, first surface 10A is a surface bonded to wire 104. In integrated circuit element 101, second surface 10B is a surface bonded to an interlayer insulating film 106. A maximum width of first surface 10A is not particularly limited, but is, for example, greater than or equal to 1 μm and less than or equal to 1 mm. A shape of first surface 10A may be any shape, and is, for example, a rectangular shape. First surface 10A has, for example, a square shape in which a length of one side is 100 μm.

Bonding pad 11 includes a surface electrode layer 1, a resistance layer 2, a stress buffer layer 3, and a connecting member 4. In bonding pad 11, resistance layer 2, stress buffer layer 3, connecting member 4, and surface electrode layer 1 are laminated in order upward in first direction Z.

Surface electrode layer 1 has first surface 10A. A material constituting surface electrode layer 1 may be any material having conductivity, but includes, for example, aluminum (Al). The material constituting surface electrode layer 1 may be a compound of Al.

As illustrated in FIG. 3, first surface 10A includes a first region R1 to which wire 104 is bonded and a second region R2 located outside first region R1. Resistance layer 2, stress buffer layer 3, and connecting member 4 are formed below each of first region R1 and second region R2.

Resistance layer 2 has second surface 10B. A material constituting resistance layer 2 may be any material having a specific resistance higher than a specific resistance of the material constituting surface electrode layer 1, but includes, for example, polysilicon.

Resistance layer 2 extends over the entire bonding pad 11 in, for example, a second direction X and a third direction Y orthogonal to first direction Z, respectively. As viewed from first direction Z, resistance layer 2 is disposed to overlap with the each of first region R1 and second region R2 of first surface 10A. As viewed from first direction Z, resistance layer 2 is disposed to overlap with the entire first surface 10A, for example. Resistance layer 2 is a continuous body continuing in second direction X and third direction Y, respectively.

Stress buffer layer 3 is disposed between surface electrode layer 1 and resistance layer 2 in first direction Z. A lower surface of stress buffer layer 3 is in contact with an upper surface of resistance layer 2. A material constituting stress buffer layer 3 has the conductivity. Stress buffer layer 3 is electrically connected to resistance layer 2.

Stress buffer layer 3 extends over the entire bonding pad 11 in second direction X and third direction Y, respectively. As viewed from first direction Z, stress buffer layer 3 is disposed to overlap with the each of first region R1 and second region R2 of first surface 10A. As viewed from first direction Z, stress buffer layer 3 is disposed to overlap with the entire first surface 10A, for example. Stress buffer layer 3 is a continuous body continuing in second direction X and third direction Y, respectively. Stress buffer layer 3 is, for example, a single layer including one continuous body continuing in first direction Z, second direction X, and third direction Y, respectively.

A rigidity modulus (a shearing modulus) of the material constituting stress buffer layer 3 is lower than a rigidity modulus (a shearing modulus) of a material constituting a plug 42 to be described later. A Young's modulus of the material constituting stress buffer layer 3 is lower than a Young's modulus of the material constituting plug 42 to be described later. The material constituting stress buffer layer 3 may be the same as the material constituting surface electrode layer 1.

As illustrated in FIG. 3, a thickness T1 of stress buffer layer 3 in first direction Z is larger than a thickness T2 of surface electrode layer 1 in first direction Z. Thickness T1 of stress buffer layer 3 in first direction Z is larger than, for example, a thickness of resistance layer 2 in first direction Z. Thickness T1 of stress buffer layer 3 in first direction Z is larger than, for example, a thickness of connecting member 4 in first direction Z. Stress buffer layer 3 is, for example, the thickest among a plurality of members constituting bonding pad 11.

Connecting member 4 is disposed between surface electrode layer 1 and stress buffer layer 3 in first direction Z, and connects surface electrode layer 1 and stress buffer layer 3. Connecting member 4 is in contact with each of surface electrode layer 1 and stress buffer layer 3.

Connecting member 4 includes an insulator 41 and a plurality of plugs 42. Insulator 41 and each of the plurality of plugs 42 are in contact with surface electrode layer 1 and stress buffer layer 3 in first direction Z, respectively. The each of the plurality of plugs 42 electrically connects surface electrode layer 1 and stress buffer layer 3.

The each of the plurality of plugs 42 are disposed at an interval in second direction X and third direction Y, respectively. The each of the plurality of plugs 42 is embedded in insulator 41. Insulator 41 is formed with a plurality of through holes penetrating insulator 41 in first direction Z. The each of the plurality of plugs 42 is formed to fill the plurality of the through holes of insulator 41.

Upper surfaces of insulator 41 and the each of the plurality of plugs 42 are in contact with a lower surface of surface electrode layer 1. Lower surfaces of insulator 41 and the each of the plurality of plugs 42 are in contact with an upper surface of stress buffer layer 3. An inner peripheral surface of each of the plurality of the through holes of insulator 41 is in contact with a side surface of the each of the plurality of plugs 42. From a different point of view, in connecting member 4, insulator 41 and the each of the plurality of plugs 42 are alternately laminated in a direction orthogonal to first direction Z. Connecting member 4 is a multilayer plug including insulator 41 and the plurality of plugs 42 alternately laminated in the direction orthogonal to first direction Z.

A material constituting insulator 41 may be any material having an electrical insulation, but is, for example, an oxide film. A material constituting the each of the plurality of plugs 42 is a material having the conductivity. The material constituting the each of the plurality of plugs 42 includes, for example, tungsten (W).

As illustrated in FIG. 4, connecting member 4 includes a third region R3 and a fourth region R4 located outside third region R3. Third region R3 is a region overlapping with first region R1 of first surface 10A to which wire 104 is bonded in first direction Z in connecting member 4. Fourth region R4 is a region overlapping with second region R2 of first surface 10A in first direction Z in connecting member 4. The plurality of plugs 42 include first plug 42 group disposed in third region R3, and second plug 42 group disposed in fourth region R4.

As illustrated in FIG. 4, an interval of the each of the plurality of plugs 42 in second direction X is, for example, constant. An interval of the each of the plurality of plugs 42 in third direction Y is, for example, constant. A width of the each of the plurality of plugs 42 in second direction X is, for example, narrower than a width of insulator 41 in second direction X, the insulator being sandwiched between two plugs 42 adjacent in second direction X. A width of the each of the plurality of plugs 42 in third direction Y is, for example, narrower than the width of insulator 41 in second direction X, the insulator being sandwiched between two plugs 42 adjacent in third direction Y.

As illustrated in FIG. 4, a cross-sectional shape of the each of the plurality of plugs 42 orthogonal to first direction Z is, for example, a rectangular shape. The cross-sectional shape of the each of the plurality of plugs 42 orthogonal to first direction Z may be, for example, a circular shape.

Although not illustrated, multilayer structure 20 of integrated circuit element 101 is further included. Multilayer structure 20 includes the first wiring layer electrically connected to surface electrode layer 1 of bonding pad 11; the second wiring layer that is laminated at an interval from the first wiring layer in first direction Z and electrically connected to resistance layer 2 of bonding pad 11; the insulating layer that is sandwiched between the first wiring layer and the second wiring layer and electrically insulates the first wiring layer and the second wiring layer; and the plug that is embedded in the insulating layer and electrically connects the first wiring layer and the second wiring layer.

In a method for manufacturing integrated circuit element 101 to be described later, resistance layer 2 and stress buffer layer 3 of bonding pad 11 can be formed in the same process for the second wiring layer and the insulating layer of multilayer structure 20. Connecting member 4 of bonding pad 11 can be formed in the same process for the insulating layer and the plug of multilayer structure 20. Surface electrode layer 1 of bonding pad 11 can be formed in the same process for the first wiring layer of multilayer structure 20.

### <Method of Manufacturing Bonding Pad 11>

As described above, in the method for manufacturing integrated circuit element 101, bonding pad 11 can be formed simultaneously with multilayer structure 20. Hereinafter, an example of the method for manufacturing bonding pad 11 will be described.

First, resistance layer 2 and stress buffer layer 3 are formed in order on interlayer insulating film 106. Stress buffer layer 3 is formed on resistance layer 2. Each of resistance layer 2 and stress buffer layer 3 is formed over an entire region where bonding pad 11 is to be formed. In multilayer structure 20, the each of resistance layer 2 and stress buffer layer 3 may have any shape as a lower wiring layer.

Second, connecting member 4 is formed on stress buffer layer 3. In the process for forming connecting member 4, insulator 41 may be formed to embed the plurality of plugs 42 after the plurality of plugs 42 are formed at first. Alternatively, in the process for forming connecting member 4, the plurality of plugs 42 may be formed to fill the plurality of the through holes, after insulator 41 is formed into a film at first and the plurality of the through holes are formed in insulator 41. Connecting member 4 is formed over the entire region where bonding pad 11 is to be formed. In multilayer structure 20, insulating layer and plug may have any shape.

Third, surface electrode layer 1 is formed on connecting member 4. The each of resistance layer 2 and stress buffer layer 3 is formed over the entire region where bonding pad 11 is to be formed. In multilayer structure 20, surface electrode layer 1 may have any shape as an upper wiring layer.

In this way, bonding pad 11 may be formed simultaneously with multilayer structure 20.

### <Effects of Bonding Pad 11>

Bonding pad 11 includes stress buffer layer 3 that is disposed between surface electrode layer 1 and resistance layer 2 in first direction Z and in contact with resistance layer 2. Stress buffer layer 3 extends over the entire bonding pad 11 in second direction X and third direction Y, respectively. Such stress buffer layer 3 disperses a stress to be generated in bonding pad 11 when wire 104 is subjected to the ultrasonic bonding to first surface 10A, and suppresses concentration of the stress on connecting member 4. Therefore, in bonding pad 11 including stress buffer layer 3, the cracks hardly occur in connecting member 4, and bondability between wire 104 and bonding pad 11 is hardly deteriorated, as compared with the conventional bonding pad described above.

Moreover, in bonding pad 11, thickness T1 of stress buffer layer 3 in first direction Z is larger than thickness T2 of surface electrode layer 1 in first direction Z. Rigidity of bonding pad 11 including such stress buffer layer 3 can be easily increased as compared with rigidity of a bonding pad including a stress buffer layer having a thickness in first direction Z equal to or smaller than the thickness of surface electrode layer 1 in first direction Z. As a result, in bonding pad 11, since rigidity required to withstand the ultrasonic vibration in direction orthogonal to first direction Z can be easily achieved, the cracks hardly occur in connecting member 4, and the bondability between wire 104 and bonding pad 11 is hardly deteriorated.

### Second Embodiment

FIG. 5 is a cross-sectional view for illustrating a bonding pad 12 according to the second embodiment. Note that, in FIG. 5, illustration or the like of interlayer insulating film 106 is omitted. As illustrated in FIG. 5, bonding pad 12 has a configuration basically similar to the configuration of bonding pad 11 according to the first embodiment and exhibits similar effects, but is different from bonding pad 11 in that stress buffer layer 3 includes a first metal layer 31 and a second metal layer 32. Hereinafter, differences between bonding pad 12 and bonding pad 11 will be mainly described.

As illustrated in FIG. 5, first metal layer 31 and second metal layer 32 are laminated on each other in first direction Z. An upper surface of first metal layer 31 is in contact with a lower surface of connecting member 4. A lower surface of first metal layer 31 is in contact with an upper surface of second metal layer 32. A lower surface of second metal layer 32 is in contact with an upper surface of resistance layer 2.

Each of first metal layer 31 and second metal layer 32 extends over the entire bonding pad 12 in second direction X and third direction Y. The each of first metal layer 31 and second metal layer 32 is a continuous body continuing in second direction X and third direction Y, respectively. The each of first metal layer 31 and second metal layer 32 is, for example, a single layer including one continuous body continuing in first direction Z, second direction X, and third direction Y, respectively.

Rigidity of a second metal material constituting second metal layer 32 is higher than rigidity of a first metal material constituting first metal layer 31. A Young's modulus of the first metal material constituting first metal layer 31 is lower than a Young's modulus of the second metal material constituting second metal layer 32. A rigidity modulus of the first metal material constituting first metal layer 31 is lower than a rigidity modulus of the second metal material constituting second metal layer 32. The Young's modulus of the first metal material constituting first metal layer 31 is lower than the Young's modulus of the material constituting the each of the plurality of plugs 42. The rigidity modulus of the first metal material constituting first metal layer 31 is lower than the rigidity modulus of the material constituting the each of the plurality of plugs 42.

The second metal material constituting second metal layer 32 is, for example, the same as the material constituting the each of the plurality of plugs 42. Note that, the Young's modulus of the second metal material constituting second metal layer 32 may be lower than the Young's modulus of the material constituting the each of the plurality of plugs 42.

A sum T1 of thicknesses of first metal layer 31 and second metal layer 32 in first direction Z is larger than thickness T2 of surface electrode layer 1 in first direction Z. Sum T1 of the thicknesses of first metal layer 31 and second metal layer 32 in first direction Z is larger than, for example, the thickness of resistance layer 2 in first direction Z. Sum T1 of the thicknesses of first metal layer 31 and second metal layer 32 in first direction Z is larger than, for example, the thickness of connecting member 4 in first direction Z.

The thickness of first metal layer 31 in first direction Z is, for example, larger than the thickness of surface electrode layer 1 in first direction Z. The thickness of second metal layer 32 in first direction Z is larger than, for example, the thickness of first metal layer 31 in first direction Z. The thickness of second metal layer 32 in first direction Z may be equal to or smaller than the thickness of first metal layer 31 in first direction Z.

In bonding pad 12, first metal layer 31 disperses a stress to be generated in bonding pad 12 when wire 104 is subjected to the ultrasonic bonding to first surface 10A, and suppresses the concentration of the stress on connecting member 4. Moreover, second metal layer 32 suppresses excessive deformation of connecting member 4 due to a weighting load in first direction Z to be applied to bonding pad 12 during the ultrasonic bonding above. Therefore, also in bonding pad 12, the cracks hardly occur in connecting member 4, and bondability between wire 104 and bonding pad 12 is hardly deteriorated, as compared with the conventional bonding pad described above.

In bonding pad 12, the second metal material constituting second metal layer 32 may be the same as the material constituting the each of the plurality of plugs 42. In this way, since types of the metal materials included in bonding pad 12 can be reduced, measures against metal contamination are facilitated and manufacturing efficiency is enhanced. Moreover, in this way, it is easy to control a deformation amount of bonding pad 12 due to the weighting load in first direction Z during the ultrasonic bonding above, and it is possible to more effectively suppress a deterioration in the bondability between wire 104 and bonding pad 12.

In bonding pad 12, the rigidity modulus of the second metal material constituting second metal layer 32 may be lower than the rigidity modulus of the material constituting the plurality of plugs 42. In this way, first metal layer 31 and second metal layer 32 can disperse a shear stress to be generated in bonding pad 12 when wire 104 is subjected to the ultrasonic bonding to first surface 10A, and can suppress the concentration of the stress on connecting member 4.

Multilayer structure 20 of integrated circuit element 101 according to second embodiment includes second metal layer 32 similarly to bonding pad 12. In a method for manufacturing integrated circuit element 101 according to the second embodiment, bonding pad 12 can be formed simultaneously with multilayer structure 20.

### Third Embodiment

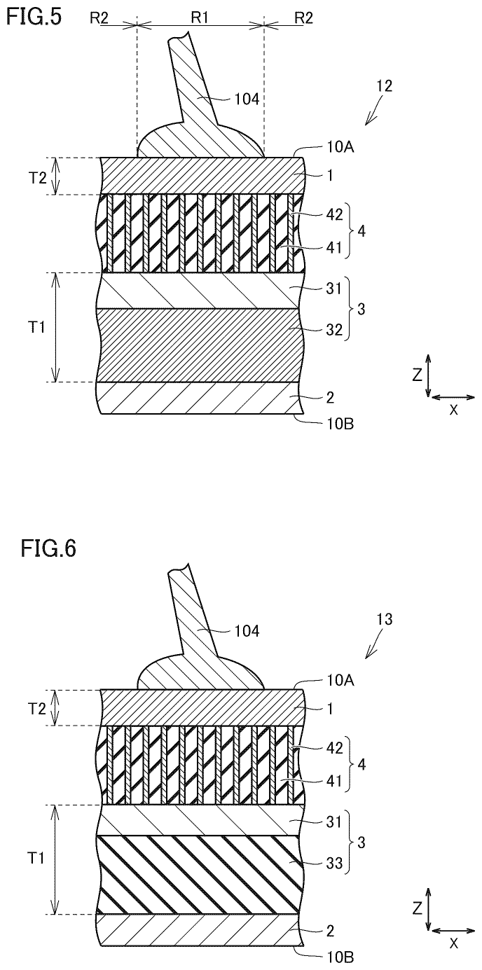

FIG. 6 is a cross-sectional view for illustrating a bonding pad 13 according to the third embodiment. Note that, in FIG. 6, the illustration or the like of interlayer insulating film 106 is omitted. As illustrated in FIG. 6, bonding pad 13 has a configuration basically similar to the configuration of bonding pad 11 according to the first embodiment and exhibits similar effects, but is different from bonding pad 11 in that stress buffer layer 3 includes first metal layer 31 and an insulating layer 33. Hereinafter, differences between bonding pad 13 and bonding pad 11 will be mainly described.

As illustrated in FIG. 6, first metal layer 31 and insulating layer 33 are laminated on each other in first direction Z. The upper surface of first metal layer 31 is in contact with the lower surface of connecting member 4. The lower surface of first metal layer 31 is in contact with an upper surface of insulating layer 33. A lower surface of insulating layer 33 is in contact with the upper surface of resistance layer 2.

Each of first metal layer 31 and insulating layer 33 extends over the entire bonding pad 13 in second direction X and third direction Y. The each of first metal layer 31 and insulating layer 33 is a continuous body continuing in second direction X and third direction Y, respectively. The each of first metal layer 31 and insulating layer 33 is, for example, a single layer including one continuous body continuing in first direction Z, second direction X, and third direction Y, respectively.

The rigidity modulus of the first metal material constituting first metal layer 31 is lower than the rigidity modulus of the material constituting the each of the plurality of plugs 42. The Young's modulus of the first metal material constituting first metal layer 31 is lower than the Young's modulus of the material constituting the each of the plurality of plugs 42.

A material constituting insulating layer 33 may be any material having the electrical insulation, but is, for example, the same as the material constituting insulator 41 of connecting member 4. Insulating layer 33 is, for example, the oxide film. A rigidity modulus of the material constituting insulating layer 33 is lower than the rigidity modulus of the material constituting the each of the plurality of plugs 42. A Young's modulus of the material constituting insulating layer 33 is lower than the Young's modulus of the material constituting the each of the plurality of plugs 42. Note that, the rigidity modulus of the material constituting insulating layer 33 may be lower than the rigidity modulus of the material constituting insulator 41.

A sum T1 of thicknesses of first metal layer 31 and insulating layer 33 in first direction Z is larger than thickness T2 of surface electrode layer 1 in first direction Z. Sum T1 of the thicknesses of first metal layer 31 and insulating layer 33 in first direction Z is larger than, for example, the thickness of resistance layer 2 in first direction Z. Sum T1 of the thicknesses of first metal layer 31 and insulating layer 33 in first direction Z is larger than, for example, the thickness of connecting member 4 in first direction Z.

The thickness of first metal layer 31 in first direction Z is, for example, larger than the thickness of surface electrode layer 1 in first direction Z. The thickness of insulating layer 33 in first direction Z is larger than, for example, the thickness of first metal layer 31 in first direction Z. The thickness of insulating layer 33 in first direction Z may be equal to or smaller than the thickness of first metal layer 31 in first direction Z.

In bonding pad 13, first metal layer 31 and insulating layer 33 disperse a stress to be generated in bonding pad 13 when wire 104 is subjected to the ultrasonic bonding to first surface 10A, and suppresses the concentration of the stress on connecting member 4. Moreover, since first metal layer 31 and insulating layer 33 easily follow the ultrasonic vibration in the direction orthogonal to first direction Z, it is possible to suppress generation of the cracks in connecting member 4 even in a case where energy of the ultrasonic vibration is set high. As a result, in bonding pad 13, the cracks hardly occur in connecting member 4, and bondability between wire 104 and bonding pad 13 is high, as compared with the conventional bonding pad described above.

Multilayer structure 20 of integrated circuit element 101 according to the third embodiment includes insulating layer 33 similarly to bonding pad 13. In a method for manufacturing integrated circuit element 101 according to the third embodiment, bonding pad 13 can be formed simultaneously with multilayer structure 20.

### Fourth Embodiment

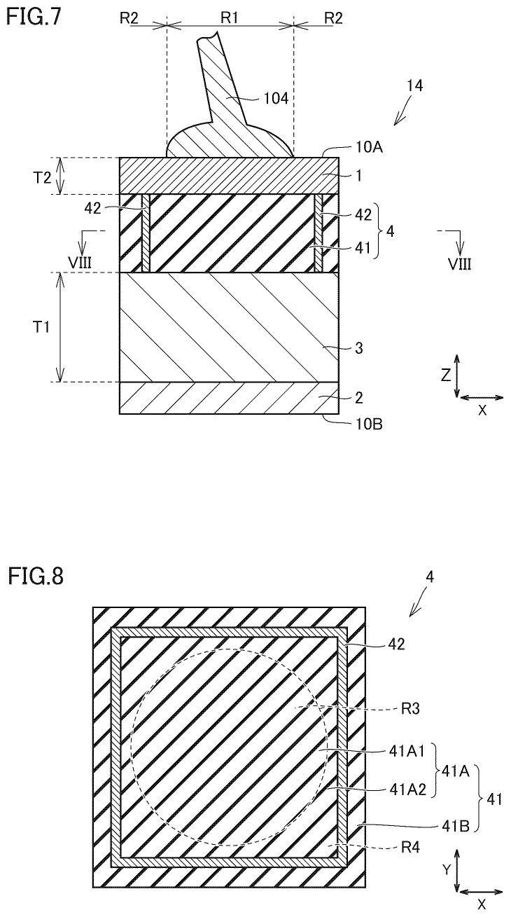

FIGS. 7 and 8 are cross-sectional views for illustrating a bonding pad 14 according to the fourth embodiment. Note that, in FIG. 7, the illustration or the like of interlayer insulating film 106 is omitted. As illustrated in FIGS. 7 and 8, bonding pad 14 has a configuration basically similar to the configuration of bonding pad 11 according to the first embodiment and exhibits similar effects, but is different from bonding pad 11 in that third region R3 of connecting member 4 includes only insulator 41, and at least one plug 42 is disposed only in fourth region R4 of connecting member 4. Hereinafter, differences between bonding pad 14 and bonding pad 11 will be mainly described.

As illustrated in FIGS. 7 and 8, connecting member 4 of bonding pad 14 includes the at least one plug 42 formed in fourth region R4, and insulator 41 formed in the entire third region R3 and a remaining portion of fourth region R4. For example, only one plug 42 is formed in fourth region R4. Note that, the plurality of plugs 42 may be formed in fourth region R4. The cross-sectional shape of plug 42 orthogonal to first direction Z is a circular shape. The cross-sectional shape of plug 42 orthogonal to first direction Z is, for example, a square annular shape. Note that, the cross-sectional shape of plug 42 orthogonal to first direction Z may be an annular shape.

Insulator 41 includes a first portion 41A disposed inside plug 42 and a second portion 41B disposed outside plug 42. First portion 41A of insulator 41 is a continuous body continuing in second direction X and third direction Y, respectively. First portion 41A of insulator 41 is, for example, a single layer including one continuous body continuing in first direction Z, second direction X, and third direction Y, respectively.

First portion 41A of insulator 41 includes a third portion 41A1 disposed in third region R3 and a fourth portion 41A2 disposed in fourth region R4. Third portion 41A1 and fourth portion 41A2 are configured as a continuous body. Second portion 41B of insulator 41 is disposed in fourth region R4.

As illustrated in FIG. 8, plug 42 is formed only in fourth region R4 as viewed in first direction Z. As viewed from first direction Z, plug 42 is disposed outside (on a fourth region R4 side) a boundary line between third region R3 and fourth region R4 at an interval from the boundary line. From a different point of view, a bonding interface between first portion 41A of insulator 41 and plug 42 as well as a bonding interface between second portion 41B of insulator 41 and plug 42 are not formed in third region R3 located immediately below first region R1 to which wire 104 is bonded.

In bonding pad 14, since the bonding interface between first portion 41A of insulator 41 and plug 42 as well as the bonding interface between second portion 41B of insulator 41 and plug 42 are not formed in third region R3, the cracks hardly develop from the bonding interfaces above to insulator 41 as compared with bonding pad 11 in which the bonding interfaces above are also formed in third region R3. Therefore, bondability between wire 104 and bonding pad 14 is higher than the bondability between wire 104 and bonding pad 11.

In a method for manufacturing integrated circuit element 101 according to the fourth embodiment, bonding pad 14 can be formed simultaneously with multilayer structure 20.

### Variation

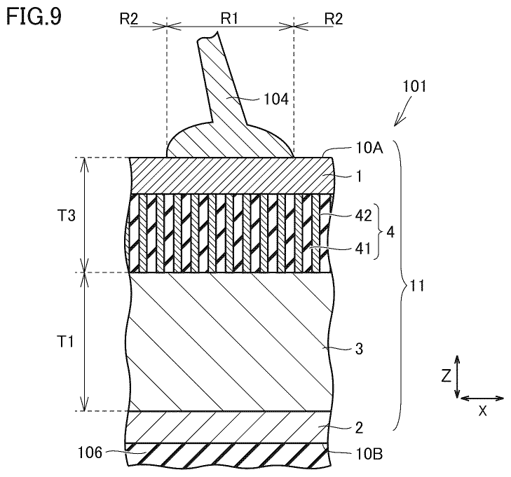

As illustrated in FIG. 9, in bonding pads 11 to 14 according to the first embodiment to the fourth embodiment, thickness T1 of stress buffer layer 3 in first direction Z may be equal to or larger than sum T3 of the thickness of surface electrode layer 1 in first direction Z and the thickness of connecting member 4 in first direction Z. In this way, stress buffer layer 3 disperses the stress to be generated in bonding pad 11, and an effect of suppressing the concentration of the stress on connecting member 4 is enhanced.

Bonding pads 11 to 14 according to first embodiment to fourth embodiment may include, instead of resistance layer 2, a bottom surface electrode layer made of a material having a specific resistance equivalent to the specific resistance of the material constituting surface electrode layer 1.

Hereinafter, various aspects of the present disclosure will be collectively described as supplementary notes.

### Supplementary Note 1

A bonding pad of an integrated circuit element included in an integrated circuit device, the bonding pad including:
a surface electrode layer having a first surface;
a resistance layer having a second surface disposed at an interval from the first surface in a first direction orthogonal to the first surface, the second surface facing a side opposite to the first surface;
a stress buffer layer disposed between the surface electrode layer and the resistance layer in the first direction; and
a connecting member connecting the surface electrode layer and the stress buffer layer in the first direction and being in contact with each of the surface electrode layer and the stress buffer layer, in which
the stress buffer layer extends over the entire bonding pad in a direction orthogonal to the first direction,
the connecting member includes an insulator that is in contact with the each of the surface electrode layer and the stress buffer layer in the first direction, and at least one plug that is in contact with the insulator in the direction orthogonal to the first direction and electrically connect the surface electrode layer and the stress buffer layer, and
a thickness of the stress buffer layer in the first direction is larger than a thickness of the surface electrode layer in the first direction.

### Supplementary Note 2

The bonding pad according to Supplementary Note 1, in which the stress buffer layer includes a first metal layer and a second metal layer laminated on each other in the first direction,
the first metal layer is in contact with the connecting member,
the second metal layer is in contact with the resistance layer,
each of the first metal layer and the second metal layer extends over the entire bonding pad in the direction orthogonal to the first direction, and
a Young's modulus of a first metal material constituting the first metal layer is lower than a Young's modulus of a second metal material constituting the second metal layer, and lower than a Young's modulus of a material constituting the at least one plug.

### Supplementary Note 3

The bonding pad according to Supplementary Note 2, in which the second metal material constituting the second metal layer is a same as the material constituting the at least one plug.

### Supplementary Note 4

The bonding pad according to Supplementary Note 2, in which a rigidity modulus of the second metal material constituting the second metal layer is lower than a rigidity modulus of the material constituting the at least one plug.

### Supplementary Note 5

The bonding pad according to Supplementary Note 1, in which the stress buffer layer includes a metal layer and an insulating layer laminated on each other in the first direction,
the metal layer is in contact with the surface electrode layer,
the insulating layer is in contact with the resistance layer,
each of the metal layer and the insulating layer extends over the entire bonding pad in the direction orthogonal to the first direction, and
a rigidity modulus of a material constituting the insulating layer is lower than the rigidity modulus of a material constituting the at least one plug.

### Supplementary Note 6

The bonding pad according to any one of Supplementary Notes 1 to 5, in which the at least one plug includes a plurality of plugs disposed at intervals between each other in the direction orthogonal to the first direction, and
the insulator is embedded between the plurality of the plugs.

### Supplementary Note 7

The bonding pad according to any one of Supplementary Notes 1 to 6, in which the first surface includes a first region to which a conductive member constituting a part of the integrated circuit device is bonded, and a second region located outside the first region,
the connecting member includes a third region overlapping with the first region in the first direction, and a fourth region overlapping with the second region in the first direction,
the at least one plug is disposed only in the fourth region of the connecting member, and
the third region of the connecting member includes the insulator.

### Supplementary Note 8

The bonding pad according to any one of Supplementary Notes 1 to 7, in which the thickness of the stress buffer layer in the first direction is greater than or equal to a total value of the thickness of the surface electrode layer in the first direction and a thickness of the connecting member in the first direction.

### Supplementary Note 9

An integrated circuit element including:
the bonding pad according to any one of Supplementary Notes 1 to 8; and
an interlayer insulating film bonded to the second surface of the bonding pad.

### Supplementary Note 10

An integrated circuit device including:
the integrated circuit element including the bonding pad according to any one of Supplementary Notes 1 to 8, and the interlayer insulating film bonded to the second surface of the bonding pad; and
a conductive member subjected to ultrasonic bonding to the first surface of the bonding pad.

Although the embodiments of the present invention have been described, it may be considered that the embodiments disclosed herein are illustrative in all respects and not restrictive. The scope of the present invention is indicated by claims, and it is intended that meanings equivalent to the claims and all modifications within the scope are included.

What is claimed is:

1. A bonding pad of an integrated circuit element included in an integrated circuit device, the bonding pad comprising:
a surface electrode layer having a first surface;
a resistance layer having a second surface disposed at an interval from the first surface in a first direction orthogonal to the first surface, the second surface facing a side opposite to the first surface;
a stress buffer layer disposed between the surface electrode layer and the resistance layer in the first direction; and
a connecting member connecting the surface electrode layer and the stress buffer layer in the first direction and being in contact with each of the surface electrode layer and the stress buffer layer, wherein
the stress buffer layer extends over the entire bonding pad in a direction orthogonal to the first direction,
the connecting member includes an insulator that is in contact with the each of the surface electrode layer and the stress buffer layer in the first direction, and at least one plug that is in contact with the insulator in the direction orthogonal to the first direction and electrically connect the surface electrode layer and the stress buffer layer, and
a thickness of the stress buffer layer in the first direction is larger than a thickness of the surface electrode layer in the first direction.

2. The bonding pad according to claim 1, wherein the stress buffer layer includes a first metal layer and a second metal layer laminated on each other in the first direction,
the first metal layer is in contact with the connecting member,
the second metal layer is in contact with the resistance layer,
each of the first metal layer and the second metal layer extends over the entire bonding pad in the direction orthogonal to the first direction, and
a Young's modulus of a first metal material constituting the first metal layer is lower than a Young's modulus of a second metal material constituting the second metal layer, and lower than a Young's modulus of a material constituting the at least one plug.

3. The bonding pad according to claim 2, wherein the second metal material constituting the second metal layer is a same as the material constituting the at least one plug.

4. The bonding pad according to claim 2, wherein a rigidity modulus of the second metal material constituting the second metal layer is lower than a rigidity modulus of the material constituting the at least one plug.

5. The bonding pad according to claim 1, wherein the stress buffer layer includes a metal layer and an insulating layer laminated on each other in the first direction,
the metal layer is in contact with the surface electrode layer,
the insulating layer is in contact with the resistance layer,
each of the metal layer and the insulating layer extends over the entire bonding pad in the direction orthogonal to the first direction, and
a rigidity modulus of a material constituting the insulating layer is lower than a rigidity modulus of a material constituting the at least one plug.

6. The bonding pad according to claim 1, wherein the at least one plug includes a plurality of plugs disposed at intervals between each other in the direction orthogonal to the first direction, and
the insulator is embedded between the plurality of the plugs.

7. The bonding pad according to claim 1, wherein the first surface includes a first region to which a conductive member constituting a part of the integrated circuit device is bonded, and a second region located outside the first region,
the connecting member includes a third region overlapping with the first region in the first direction, and a fourth region overlapping with the second region in the first direction,
the at least one plug is disposed only in the fourth region of the connecting member, and
the third region of the connecting member includes the insulator.

8. The bonding pad according to claim 1, wherein the thickness of the stress buffer layer in the first direction is greater than or equal to a total value of a thickness of the surface electrode layer in the first direction and a thickness of the connecting member in the first direction.

9. An integrated circuit element comprising:
the bonding pad according to claim 1; and
an interlayer insulating film bonded to the second surface of the bonding pad.

10. An integrated circuit device comprising:
the integrated circuit element including the bonding pad according to claim 1, and an interlayer insulating film bonded to the second surface of the bonding pad; and
a conductive member subjected to ultrasonic bonding to the first surface of the bonding pad.

11. The bonding pad according to claim 2, wherein the at least one plug includes a plurality of plugs disposed at intervals between each other in the direction orthogonal to the first direction, and
the insulator is embedded between the plurality of the plugs.

12. The bonding pad according to claim 2, wherein the first surface includes a first region to which a conductive member constituting a part of the integrated circuit device is bonded, and a second region located outside the first region,
the connecting member includes a third region overlapping with the first region in the first direction, and a fourth region overlapping with the second region in the first direction,
the at least one plug is disposed only in the fourth region of the connecting member, and
the third region of the connecting member includes the insulator.

13. The bonding pad according to claim 2, wherein the thickness of the stress buffer layer in the first direction is greater than or equal to a total value of a thickness of the surface electrode layer in the first direction and a thickness of the connecting member in the first direction.

14. An integrated circuit element comprising:
the bonding pad according to claim 2; and
an interlayer insulating film bonded to the second surface of the bonding pad.

15. An integrated circuit device comprising:
the integrated circuit element including the bonding pad according to claim 2, and an interlayer insulating film bonded to the second surface of the bonding pad; and
a conductive member subjected to ultrasonic bonding to the first surface of the bonding pad.

16. The bonding pad according to claim 3, wherein the at least one plug includes a plurality of plugs disposed at intervals between each other in the direction orthogonal to the first direction, and
the insulator is embedded between the plurality of the plugs.

17. The bonding pad according to claim 3, wherein the first surface includes a first region to which a conductive member constituting a part of the integrated circuit device is bonded, and a second region located outside the first region,
the connecting member includes a third region overlapping with the first region in the first direction, and a fourth region overlapping with the second region in the first direction,
the at least one plug is disposed only in the fourth region of the connecting member, and
the third region of the connecting member includes the insulator.

18. The bonding pad according to claim 3, wherein the thickness of the stress buffer layer in the first direction is greater than or equal to a total value of a thickness of the surface electrode layer in the first direction and a thickness of the connecting member in the first direction.

19. An integrated circuit element comprising:
the bonding pad according to claim 3; and
an interlayer insulating film bonded to the second surface of the bonding pad.

20. An integrated circuit device comprising:
the integrated circuit element including the bonding pad according to claim 3, and an interlayer insulating film bonded to the second surface of the bonding pad; and
a conductive member subjected to ultrasonic bonding to the first surface of the bonding pad.
